(19) United States
(12) Patent Application Publication
(10) Pub. No.: US 2025/0017042 A1
(43) Pub. Date: Jan. 9, 2025

(54) DISPLAY DEVICE

(71) Applicant: LG Display Co., Ltd., Seoul (KR)

(72) Inventors: Jeong-Rim SEO, Paju-si (KR); Soo-Hong CHOI, Paju-si (KR); Hong-Jae SHIN, Paju-si (KR)

(21) Appl. No.: 18/583,554

(22) Filed: Feb. 21, 2024

(30) Foreign Application Priority Data
Feb. 28, 2023 (KR) 10-2023-0027207

(51) Int. Cl. H10K 59/121; H10K 59/131

(52) U.S. Cl. CPC H10K 59/1213; H10K 59/131

(57) ABSTRACT

A display device includes a substrate including a display area and a non-display area adjacent to the display area. The display area includes a subpixel. The display device includes a light emitting diode in the subpixel and over the substrate. The display device includes a gate driving circuit disposed in the non-display area. The display device includes the gate driving circuit generating a gate signal and including a plurality of blocks. The display device includes a first transistor disposed in the gate driving circuit and including a first channel. The display device includes a second transistor disposed in the gate driving circuit and including a second channel. A first length direction of the first channel is parallel to a second length direction of the second channel.

### CROSS-REFERENCE TO RELATED APPLICATIONS

The present application claims the priority benefit of Korean Patent Application No. 10-2023-0027207, filed in Republic of Korea on Feb. 28, 2023, which is hereby incorporated by reference herein in its entirety into the present application.

### BACKGROUND

### Technical Field

The present disclosure relates to a display device, and more particularly, to a display device including a plurality of transistors, which have an uniform property, in a gate driving circuit.

### Description of the Related Art

Recently, with the advent of an information-oriented society, the interest in information displays for processing and displaying a massive amount of information and the demand for portable information media have increased. As such, a display field has rapidly advanced. Thus, various light and thin flat panel display devices have been developed and highlighted.

Among the various flat panel display devices, an organic light emitting diode (OLED) display device, e.g., an OLED display apparatus, is an emissive type device that does not include a backlight unit used in a non-emissive type device such as a liquid crystal display (LCD) device. As a result, the OLED display device has advantages in a viewing angle, a contrast ratio and a power consumption to be applied to various fields.

The OLED display device includes a data driving unit and a gate driving circuit for driving a pixel.

### BRIEF SUMMARY

Recently, a gate in panel (GIP) display device, where the gate driving circuit is formed on a substrate including the pixel, has been introduced. Here, a plurality of lines and a plurality of transistors are included in the gate driving circuit. In the related art display device, the plurality of transistors in the gate driving circuit have different properties. Due to the gate driving circuit having different properties, a desired driving property often cannot be provided. Accordingly, the present disclosure is directed to a display device that substantially obviates one or more of the problems due to limitations and disadvantages of the related art.

Various embodiments of the present disclosure provide a display device including at least two transistors, which have the same length direction of a channel, in a gate driving circuit.

Various embodiments of the present disclosure provide a display device including at least two transistors, where an extension direction of each of a gate electrode, a source electrode and a drain electrode is same as an extension direction of a connection line, in a gate driving circuit.

Additional features and advantages of the disclosure will be set forth in the description which follows, and in part will be apparent from the description, or can be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, a display device includes: a substrate including a display area and a non-display area surrounding the display area, the display area including a subpixel; a gate driving circuit disposed in the non-display area, the gate driving circuit generating a gate signal and including a plurality of blocks; a first transistor disposed in the gate driving circuit and including a first channel; and a second transistor disposed in the gate driving circuit and including a second channel, wherein a first length direction of the first channel is parallel to a second length direction of the second channel.

It is to be understood that both the foregoing general description and the following detailed description are explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a view showing a display device according to an embodiment of the present disclosure;

FIG. 2 is a block diagram showing first and second gate driving circuits and a display panel of a display device according to an embodiment of the present disclosure;

FIG. 3 is a circuit diagram showing a subpixel of a display device according to an embodiment of the present disclosure;

FIG. 4 is a circuit diagram showing a subpixel of a 3T1C structure of a display device according to an embodiment of the present disclosure;

FIG. 5 is a cross-sectional view showing a subpixel of a display device according to an embodiment of the present disclosure;

FIG. 6 is a schematic plan view showing a part of a display area and a gate driving circuit of a display device according to an embodiment of the present disclosure;

FIG. 7 is a cross-sectional view taken along a line VII-VII′ in FIG. 6;

FIG. 8 is a cross-sectional view taken along a line VIII-VIII′ in FIG. 6; and

FIG. 9 is a schematic plan view showing a transistor in a gate driving circuit of a display device according to an embodiment of the present disclosure.

### DETAILED DESCRIPTION

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure can be sufficiently thorough and complete to assist those skilled in the art to fully understand the scope of the present disclosure. Further, the present disclosure is only defined by scopes of claims.

Where the terms “comprise,” “have,” “include,” and the like are used, one or more other elements may be added unless the term, such as “only,” is used. An element described in the singular form is intended to include a plurality of elements, and vice versa, unless the context clearly indicates otherwise.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. Like reference numerals refer to like elements throughout the specification, unless otherwise specified.

In the following description, where the detailed description of the relevant known function or configuration may unnecessarily obscure a feature or aspect of the present disclosure, a detailed description of such known function or configuration may be omitted or a brief description may be provided.

In construing an element, the element is to be construed as including an error or a tolerance range even where no explicit description of such an error or tolerance range is provided.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third layer or element may be interposed therebetween.

Although the terms “first,” “second,” A, B, (a), (b), and the like may be used herein to refer to various elements, these elements should not be interpreted to be limited by these terms as they are not used to define a particular order or precedence. These terms are only used to distinguish one element from another. For example, a first element could be termed a second element, and, similarly, a second element could be termed a first element, without departing from the scope of the present disclosure.

The term “at least one” should be understood to include all combinations of one or more of related elements. For example, the term of “at least one of first, second and third elements” may include all combinations of two or more of the first, second and third elements as well as the first, second or third element.

The term “display device” may include a display device in a narrow sense such as liquid crystal module (LCM), an organic light emitting diode (OLED) module and a quantum dot (QD) module including a display panel and a driving unit for driving the display panel. In addition, the term “display device” may include a complete product (or a final product) including the LCM, the OLED module and the QD module such as a notebook computer, a television, a computer monitor, an equipment display device including an automotive display apparatus or a shape other than a vehicle, and a set electronic apparatus or a set device (or a set apparatus) such as a mobile electronic apparatus of a smart phone or an electronic pad.

Accordingly, a display device of the present disclosure may include an applied product or a set device of a final user's device including the LCM, the OLED module and the QD module as well as a display device in a narrow sense such as the LCM, the OLED module and the QD module.

According to circumstances, the LCM, the OLED module and the QD module having a display panel and a driving unit may be expressed as “a display device,” and an electronic apparatus of a complete product including the LCM, the OLED module and the QD module may be expressed as “a set device.” For example, a display device in a narrow sense may include a display panel of a liquid crystal, an organic light emitting diode and a quantum dot and a source printed circuit board (PCB) of a control unit for driving the display panel, and a set device may further include a set PCB of a set control unit electrically connected to the source PCB for controlling the entire set device.

The display panel of the present disclosure may include all kinds of display panels such as a liquid crystal display panel, an organic light emitting diode display panel, a quantum dot display panel and an electroluminescent display panel. The display panel of the present disclosure is not limited to a specific display panel of a bezel bending having a flexible substrate for an organic light emitting diode display panel and a lower back plate supporter. A shape or a size of the display panel for the display device of the present disclosure is not limited thereto.

For example, when the display panel is an organic light emitting diode display panel, the display panel may include a plurality of gate lines, a plurality of data lines and a subpixel in a crossing region of the plurality of gate lines and the plurality of data lines. The display panel may include an array having a thin film transistor of an element for selectively applying a voltage to each subpixel, an emitting element layer on the array and an encapsulating substrate or an encapsulation part covering the emitting element layer. The encapsulation part may protect the thin film transistor and the emitting element layer from an external impact and may prevent or at least reduce penetration of a moisture or an oxygen into the emitting element layer. In addition, a layer on the array may include an inorganic light emitting layer, for example, a nano-sized material layer or a quantum dot.

The thin film transistor of the present disclosure may include one of an oxide thin film transistor, an amorphous silicon thin film transistor, a low temperature polycrystalline silicon thin film transistor.

Features of various embodiments of the present disclosure may be partially or entirely coupled to or combined with each other. They may be linked and operated technically in various ways as those skilled in the art can sufficiently understand. The embodiments may be carried out independently of or in association with each other in various combinations.

Hereinafter, a display device according to various example embodiments of the present disclosure where an influence on an oxide semiconductor layer of a thin film transistor of a driving element part is reduced by shielding a light emitted and transmitted from a subpixel and/or a light inputted from an exterior will be described in detail with reference to the accompanying drawings.

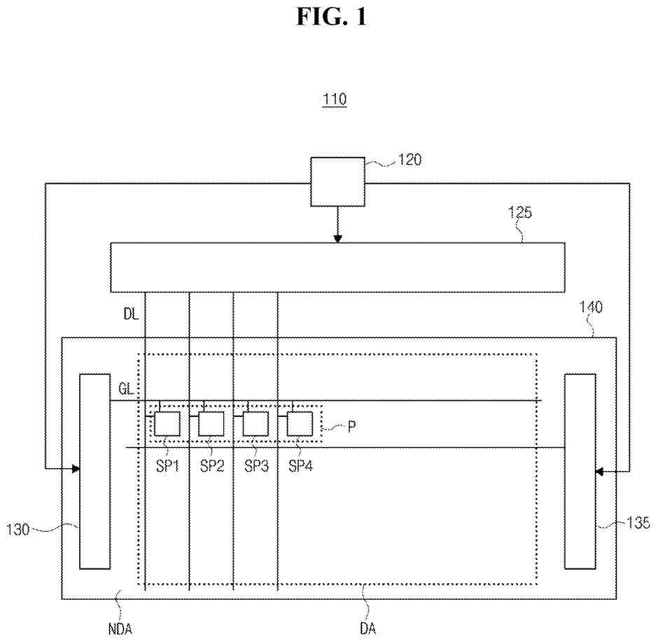

FIG. 1 is a view showing a display device according to an embodiment of the present disclosure. The display device may be an organic light emitting diode (OLED) display device.

In FIG. 1, a display device 110 according to an embodiment of the present disclosure includes a timing controlling unit 120, a data driving unit 125 and a display panel 140 including first and second gate driving circuits 130 and 135.

The timing controlling unit 120 generates an image data, a data control signal and a gate control signal using an image signal and a plurality of timing signals including a data enable signal, a horizontal synchronization signal, a vertical synchronization signal and a clock signal transmitted from an external system such as a graphic card or a television system. The image data and the data control signal are transmitted to the data driving unit 125, and the gate control signal is transmitted to the first and second gate driving circuits 130 and 135.

The data driving unit 125 generates a data signal (a data voltage) Vdata (of FIG. 3) using the data control signal and the image data transmitted from the timing controlling unit 120 and transmits the data signal to a data line DL of the display panel 140.

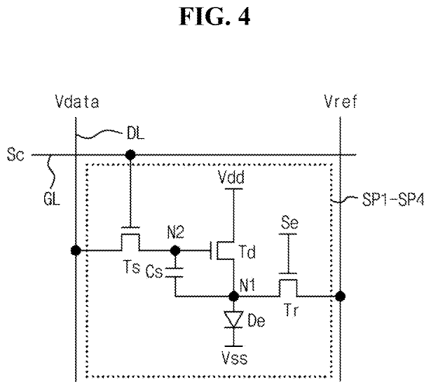

The first and second gate driving circuits 130 and 135 generate a gate signal (a gate voltage) using the gate control signal transmitted from the timing controlling unit 120 and applies the gate signal to a gate line GL of the display panel 140. For example, the gate signal may include a scan signal Sc (of FIG. 4), a sensing signal Se (of FIG. 4) and an emission signal.

The first and second gate driving circuits 130 and 135 may be a gate in panel (GIP) type formed in a non-display area NDA of a substrate of the display panel 140 having the gate line GL, the data line DL and a pixel P.

Although the first and second gate driving circuits 130 and 135 are disposed in both side portions of the display panel 140 in the embodiment of FIG. 1, one gate driving circuit may be disposed in one side portion of the display panel 140 in another embodiment.

The display panel 140 includes a display area DA at a central portion thereof and a non-display area NDA adjacent to and surrounding the display area DA. The display panel 140 displays an image using the gate signal and the data signal Vdata. For displaying an image, the display panel 140 includes a plurality of pixels P, a plurality of gate lines GL and a plurality of data lines DL in the display area DA.

Each of the plurality of pixels P includes first, second, third and fourth subpixels SP1, SP2, SP3 and SP4, and the gate line GL and the data line DL cross each other to define the first, second, third and fourth subpixels SP1, SP2, SP3 and SP4. Each of the first, second, third and fourth subpixels SP1, SP2, SP3 and SP4 is connected to the gate line GL and the data line DL. For example, the first, second, third and fourth subpixels SP1, SP2, SP3 and SP4 may correspond to red, green, blue and white, respectively.

When the display device 110 is an OLED display device, each of the first, second, third and fourth subpixels SP1, SP2, SP3 and SP4 may include a plurality of transistors such as a switching transistor Ts (of FIG. 4), a driving transistor Td (of FIG. 4) and a reference transistor Tr (of FIG. 4), a storage capacitor Cs (of FIG. 4) and a light emitting diode De (of FIG. 4).

A structure and an operation of the first and second gate driving circuits 130 and 135 and the first, second, third and fourth subpixels SP1, SP2, SP3 and SP4 of the display device 110 will be illustrated with reference to a drawing.

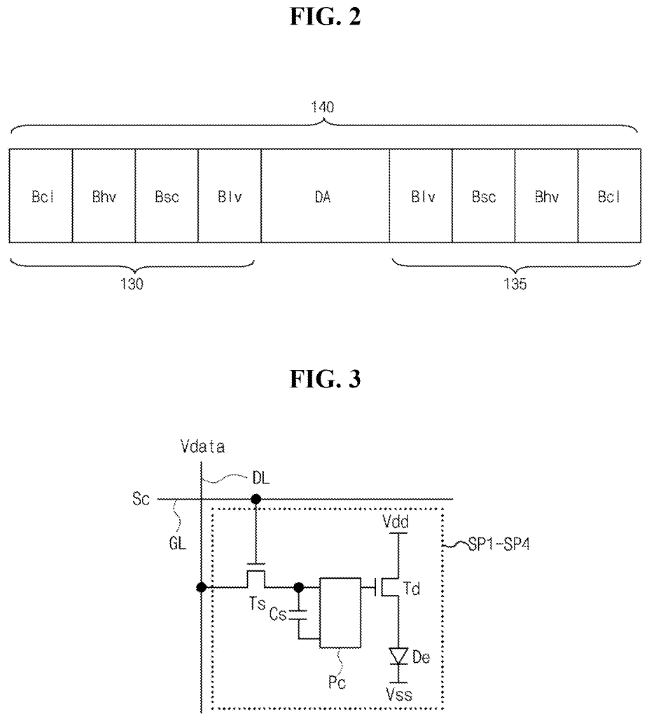

FIG. 2 is block diagram showing first and second gate driving circuits and a display panel of a display device according to an embodiment of the present disclosure, and FIG. 3 is a circuit diagram showing a subpixel of a display device according to an embodiment of the present disclosure. The display device 110 may be an organic light emitting diode (OLED) display device.

In FIG. 2, each of the first and second gate driving circuits 130 and 135 of the display device 110 according to an embodiment of the present disclosure includes a clock signal block Bcl, a high level voltage block Bhv, a stage circuit block Bsc and a low level voltage block Blv, and the display area DA is disposed between the first and second gate driving circuits 130 and 135.

In another embodiment, the disposition structure of the clock signal block Bcl, the high level voltage block Bhv, the stage circuit block Bsc and the low level voltage block Blv in the first and second gate driving circuits 130 and 135 may be variously changed.

Each of the first and second gate driving circuits 130 and 135 may include a shift register including a plurality of stages connected to each other in a cascade type.

The clock signal block Bcl includes a plurality of clock lines transmitting a clock signal used in the stage circuit block Bsc.

For example, the clock signal may include a carry clock transmitted between one stage and another stage of the shift register, a scan clock used for generation of the scan signal Sc of the gate signal supplied to the display area DA of the display panel 140 and a sensing clock used for generation of the sensing signal Se of the gate signal supplied to the display area DA of the display panel 140.

The clock signal block Bcl may include a carry clock block including the clock line transmitting the carry clock, a scan clock block including the clock line transmitting the scan clock and a sensing clock block including the clock line transmitting the sensing clock.

The high level voltage block Bhv includes a plurality of power lines transmitting the high level voltage and the control signal of the first and second gate driving circuits 130 and 135.

For example, the high level voltage of the first and second gate driving circuits 130 and 135 may include a high level voltage for a shift register and a high level voltage for an inverter of each stage, and the control signal of the first and second gate driving circuits 130 and 135 may include a start signal corresponding to an operation start of a first stage, a reset signal corresponding to an operation end of a last stage and a real time signal used for generation of a compensation signal in an operation for a real time compensation.

The stage circuit block Bsc as one stage of the shift register generates and outputs the gate signal including the carry signal, the scan signal Sc and the sensing signal Se. The carry signal is transmitted to the other stage, and the scan signal Sc and the sensing signal Se are transmitted to the display area DA.

For example, the stage circuit block Bsc may include a compensation block for an operation of a real time compensation, a carry block including a line transmitting the carry signal to the other stage, a logic block substantially generating a plurality of output signals and a buffer block outputting the scan signal Sc and the sensing signal Se of the gate signal supplied to the display area DA of the display panel 140.

The stage circuit block Bsc may include a plurality of transistors and a plurality of capacitors.

The low level voltage block Blv includes the plurality of power lines transmitting the low level voltage of the first and second gate driving circuits 130 and 135.

In the first and second gate driving circuits 130 and 135, the stage block Bsc generates the carry signal, the scan signal Sc and the sensing signal Se using the carry clock, the scan clock and the sensing clock transmitted from the clock signal block Bcl. The carry signal is transmitted to the other stage circuit block Bsc, and the scan signal Sc and the sensing signal Se are transmitted to each subpixel SP1, SP2, SP3 and SP4 of the display area DA.

In FIG. 3, each of the first, second, third and fourth subpixels SP1, SP2, SP3 and SP4 of the display panel 140 of the display device 110 according to an embodiment of the present disclosure includes a switching transistor Ts, a driving transistor Td, a compensation part Pc, a storage capacitor Cs and a light emitting diode De. The switching transistor Ts and the driving transistor Td may be an oxide semiconductor thin film transistor or a low temperature polycrystalline silicon thin film transistor.

The switching transistor Ts is switched according to the scan signal Sc of the gate signal. A gate electrode of the switching transistor Ts is connected to the scan signal Sc, a source electrode of the switching transistor Ts is connected to a first capacitor electrode of the storage capacitor Cs and the compensation part Pc, and a drain electrode of the switching transistor Ts is connected to the data signal Vdata.

The driving transistor Td is switched according to a voltage of the compensation part Pc. A gate electrode of the driving transistor Td is connected to the compensation part Pc, a source electrode of the driving transistor Td is connected to an anode of the light emitting diode De, and a drain electrode of the driving transistor Td is connected to the high level voltage Vdd.

The compensation part Pc is connected among the switching transistor Ts, the driving transistor Td and the storage capacitor Cs and compensates a variation of the threshold voltage Vth of the driving transistor Td.

The storage capacitor Cs stores the data signal Vdata. A first capacitor electrode of the storage capacitor Cs is connected to the source electrode of the switching transistor Ts and the compensation part Pc, and a second capacitor electrode of the storage capacitor Cs is connected to the compensation part Pc.

The light emitting diode De is connected between the driving transistor Td and the low level voltage Vss and emits a light of a luminance proportional to a current of the driving transistor Td. An anode of the light emitting diode De is connected to the source electrode of the driving transistor Td, and a cathode of the light emitting diode De is connected to the low level voltage Vss.

The data signal Vdata is supplied from the data driving unit 125 to each subpixel SP1, SP2, SP3 and SP4 of the display panel 140, and the scan signal Sc of the gate signal is supplied from the first and second gate driving circuits 130 and 135 to each subpixel SP1, SP2, SP3 and SP4 of the display panel 140.

Each of the first, second, third and fourth subpixels SP1, SP2, SP3 and SP4 may have one of 3T1C structure including three transistors and one capacitor, 6T1C structure including six transistors and one capacitor, 7T1C structure including seven transistors and one capacitor and 8T1C structure including eight transistors and one capacitor.

A 3T1C structure of each subpixel SP1, SP2, SP3 and SP4 will be illustrated with reference to a drawing.

FIG. 4 is a circuit diagram showing a subpixel of a 3T1C structure of a display device according to an embodiment of the present disclosure.

In FIG. 4, each of the first, second, third and fourth subpixels SP1, SP2, SP3 and SP4 of the display panel 140 of the display device 110 according to an embodiment of the present disclosure includes a switching transistor Ts, a driving transistor Td, a reference transistor Tr, a storage capacitor Cs and a light emitting diode De. The switching transistor Ts, the driving transistor Td and the reference transistor Tr may be an oxide semiconductor thin film transistor or a low temperature polycrystalline silicon thin film transistor.

The switching transistor Ts is switched according to a scan signal Sc of the gate signal. A gate electrode of the switching transistor Ts is connected to the scan signal Sc, a source electrode of the switching transistor Ts is connected to a first capacitor electrode of the storage capacitor Cs and a gate electrode of the driving transistor Td, and a drain electrode of the switching transistor Ts is connected to the data signal Vdata.

The driving transistor Td is switched according to a voltage of the first capacitor electrode of the storage capacitor Cs. A gate electrode of the driving transistor is connected to the source electrode of the switching transistor Ts and the first capacitor electrode of the storage capacitor Cs, a source electrode of the driving transistor Td is connected to a second capacitor electrode of the storage capacitor Cs, an anode of the light emitting diode De and a source electrode of the reference transistor Tr, and a drain electrode of the driving transistor Td is connected to the high level voltage Vdd.

The storage capacitor Cs stores the data signal Vdata compensated with a threshold voltage Vth of the driving transistor Td. The first capacitor electrode of the storage capacitor Cs is connected to the source electrode of the switching transistor Ts and the gate electrode of the driving transistor Td, and the second capacitor electrode of the storage capacitor Cs is connected to the source electrode of the driving transistor Td, the source electrode of the reference transistor Tr and the anode of the light emitting diode De.

The light emitting diode De is connected between the driving transistor Td and the low level voltage Vss and emits a light of a luminance proportional to a current of the driving transistor Td. The anode of the light emitting diode De is connected to the source electrode of the driving transistor Td, the second capacitor electrode of the storage capacitor Cs and the source electrode of the reference transistor Tr, and a cathode of the light emitting diode De is connected to the low level voltage Vss.

The data signal Vdata and the reference signal Vref are supplied from the data driving unit 125 to each subpixel SP1 to SP4 of the display panel 140, and the scan signal Sc and the sensing signal Se of the gate signal are supplied from the first and second gate driving circuits 130 and 135 to each subpixel SP1 to SP4 of the display panel 140.

The source electrode of the driving transistor Td, the source electrode of the reference transistor Tr, the second capacitor electrode of the storage capacitor Cs and the anode of the light emitting diode De are connected to each other to constitute a first node N1, and the gate electrode of the driving transistor Td, the source electrode of the switching transistor Ts and the first capacitor electrode of the storage capacitor Cs are connected to each other to constitute a second node N2.

In the display device 110, during an initialization period where the reference transistor Tr is turned on, the reference signal Vref is supplied to the first node N1 and the first and second nodes N1 and N2 are initialized. During a writing period where the switching transistor Ts is turned on and off, the data signal Vdata is applied to the second node N2 and the threshold voltage of the driving transistor Td is stored in the storage capacitor Cs. During a sensing period where the reference transistor Tr is turned on again, the data driving unit 125 detects the threshold voltage of the driving transistor Td stored in the storage capacitor Cs and transmits the threshold voltage to the timing controlling unit 120.

Next, the timing controlling unit 120 modifies the data signal Vdata to generate a compensated data signal where the threshold voltage is compensated and supply the compensated data signal to each subpixel SP1 to SP4 through the data driving unit 125. During an emission period where the switching transistor Ts is turned on, a current corresponding to the compensated data signal is supplied to the light emitting diode De through the driving transistor Td and the light emitting diode De emits a light.

A cross-sectional structure of each subpixel will be illustrated with reference to a drawing.

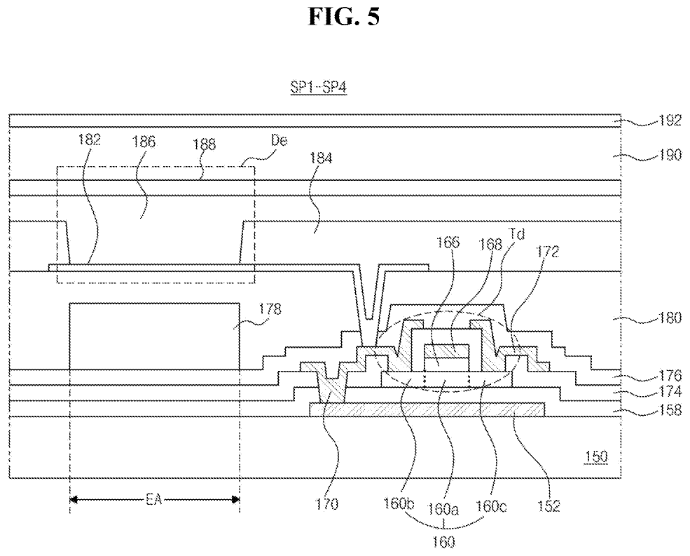

FIG. 5 is a cross-sectional view showing a subpixel of a display device according to an embodiment of the present disclosure.

In FIG. 5, each subpixel SP1 to SP4 of the display device 110 according to an embodiment of the present disclosure includes the driving transistor Td and the light emitting diode De.

The substrate 150 may be a glass substrate or a plastic substrate. For example, the substrate 150 may has a multi-layered structure including an organic layer and an inorganic layer which are alternately laminated. In an aspect of the present disclosure, the substrate 150 may include an organic insulating material layer such as polyimide (PI) and an inorganic insulating material layer such as silicon oxide (SiO2) alternately laminated.

A light shielding layer 152 is disposed on the substrate 150. For example, the light shielding layer 152 may include at least one of molybdenum (Mo), aluminum (Al), chromium (Cr), gold (Au), titanium (Ti), nickel (Ni), neodymium (Nd), copper (Cu) and an alloy thereof. The light shielding layer 152 may have a single-layered structure or a multi-layered structure.

A first capacitor pattern may be disposed on the substrate 150. The light shielding layer 152 and the first capacitor pattern may be formed by a single mask process. The light shielding layer 152 and the first capacitor pattern may be disposed on the same layer and formed of the same material as each other.

A buffer layer 158 is disposed on the light shielding layer 152. The buffer layer 158 may be disposed over the entire substrate 150. The buffer layer 158 may block a moisture penetrable from an exterior. For example, the buffer layer 158 may include an inorganic material such as silicon oxide (SiO2) or silicon nitride (SiNx). The buffer layer 158 may have a single-layered structure or a multi-layered structure.

An active layer 160 are disposed on the buffer layer 158 corresponding to the light shielding layer 152. In addition, a second capacitor pattern may be disposed on the buffer layer 158 corresponding to the first capacitor pattern.

The active layer 160 and the second capacitor pattern may be formed by a single mask process. The active layer 160 and the second capacitor pattern may be disposed on the same layer and formed of the same material as each other. For example, each of the active layer 160 and the second capacitor pattern may include polycrystalline silicon or oxide semiconductor material.

The active layer 160 may have a channel region 160a at a central portion thereof and source and drain regions 160b and 160c at both sides of the channel region 160a. The channel region 160a may include an intrinsic semiconductor material without an impurity, and each of the source and drain regions 160b and 160c may include an impurity-doped semiconductor material.

The first capacitor pattern, the buffer layer 158 and the second capacitor pattern constitute a first storage capacitor.

A patterned gate insulating layer 166 is disposed on the active layer 160. The gate insulating layer 166 may include an inorganic insulating material such as silicon oxide (SiO2) and silicon nitride (SiNx). The gate insulating layer 166 may have a single-layered structure or a multi-layered structure.

A gate electrode 168 is disposed on the gate insulating layer 160. The gate electrode 168 corresponds to the channel region 160a of the active layer 160. A gate line is disposed on the gate insulating layer 160. The gate electrode 168 and the gate line may be formed by a single mask process. The gate electrode 168 and the gate line may be disposed on the same layer and formed of the same material as each other.

For example, each of the gate electrode 168 and the gate line may include one of molybdenum (Mo), aluminum (Al), chromium (Cr), gold (Au), titanium (Ti), nickel (Ni), neodymium (Nd), copper (Cu) and an alloy thereof. Each of the gate electrode 168 and the gate line may have a single-layered structure or a multi-layered structure.

The impurity of the source region 160b and the drain region 160c of the active layer 160 may be doped using the gate electrode 168 as a blocking mask. As a result, the gate electrode 168 and the channel region 160a may have the same area and completely overlap with each other.

A first interlayer insulating layer 174, which includes contact holes respectively exposing the source region 160b and the drain region 160c of the active layer 160, is disposed on the gate electrode 168 and the gate line. In addition, a contact hole exposing a portion of the light shielding layer 152 may be formed through the first interlayer insulating layer 174 and the buffer layer 158. The first interlayer insulating layer 174 may include an inorganic insulating material such as silicon oxide (SiO2) or silicon nitride (SiNx) and may have a single-layered structure or a multi-layered structure.

A source electrode 170 and a drain electrode 172, which are spaced apart from each other, are disposed on the first interlayer insulating layer 174. The source electrode 170 contacts the source region 160b, and the drain electrode 172 contacts the drain region 160c. In addition, the source electrode 170 may contact the light shielding layer 152.

The source electrode 170 and the drain electrode 172 may be formed by a single mask process. The source electrode 170 and the drain electrode 172 may be disposed on the same layer and formed of the same material as each other.

For example, each of the source electrode 170 and the drain electrode 172 may include one of molybdenum (Mo), aluminum (Al), chromium (Cr), gold (Au), titanium (Ti), nickel (Ni), neodymium (Nd), copper (Cu) and an alloy thereof. Each of the source electrode 170 and the drain electrode 172 may have a single-layered structure or a multi-layered structure.

The active layer 160, the gate electrode 168, the source electrode 170 and the drain electrode 172 constitute the driving transistor Td.

A second interlayer insulating layer 176 is disposed on the source electrode 170 and the drain electrode 172. The second interlayer insulating layer 176 may be disposed over the entire substrate 150. The second interlayer insulating layer 176 may include an inorganic insulating material such as silicon oxide (SiO2) or silicon nitride (SiNx) and may have a single-layered structure or a multi-layered structure.

A color filter layer 178 is disposed in an emission area EA on the second interlayer insulating layer 176. For example, the color filter layer 178 may include red, green and blue color filters respectively corresponding to the first, second and third subpixels SP1, SP2 and SP3.

In FIG. 5, the second interlayer insulating layer 176 is disposed on the source and drain electrodes 170 and 172, and the color filter layer 178 is disposed on the second interlayer insulating layer 176. Alternatively, the second interlayer insulating layer 176 may be omitted, and the color filter layer 178 may be disposed on the first interlayer insulating layer 174.

The red color filter may include at least one of a red dye and a red pigment, the green color filter may include at least one of a green dye and a green pigment, and the blue color filter may include at least one of a blue dye and a blue pigment.

A color conversion layer may be disposed between a light emitting diode De and the color filter layer 178. The color conversion layer may include a red color conversion layer, a green color conversion layer and a blue color conversion layer respectively corresponding to the red subpixel, the green subpixel and the blue subpixel. For example, the color conversion layer may include a quantum dot.

An overcoat layer 180 is disposed on the color filter layer 178. The overcoat layer 180 may be disposed over the entire substrate 150. The overcoat layer 180 may include an organic insulating material such as polyimide (PI) and acrylic resin. A contact hole exposing the source electrode 170 is formed through the overcoat layer 180 and the second interlayer insulating layer 176.

A lower electrode 182 is disposed on the overcoat layer 180 and is connected to the source electrode 170 through the contact hole in the overcoat layer 180 and the interlayer insulating layer 176. The lower electrodes 182 in the subpixels SP1 to SP4 are separated from each other.

The lower electrode 182 may include a transparent conductive material. For example, the lower electrode 182 may include a material having a relatively high work function, e.g., indium tin oxide (ITO) and indium zinc oxide (IZO).

The lower electrode 182 extends from the emission area EA to overlap the second capacitor pattern. The second capacitor pattern, the second interlayer insulating layer 176 and the lower electrode 182 constitute a second storage capacitor.

The first and second storage capacitors Cs1 and Cs2 are connected to each other in parallel to constitute the storage capacitor Cs (of FIG. 3).

A bank layer 184 is disposed on the lower electrode 182 to cover an edge portion of the lower electrode 182. The bank layer 184 has an opening exposing a central portion of the lower electrode 182, and the opening of the bank layer 184 corresponds to the emission area EA.

For example, the bank layer 184 may include an opaque material (e.g., black material) to prevent a light interference between the adjacent subpixels SP1 to SP4. The bank layer 184 may include a light shielding material of at least one of a color pigment and an organic black.

Although not shown, a spacer may be disposed on the bank layer 184.

An emitting layer 186 is disposed on the bank layer 184 and the lower electrode 182 exposed through the opening of the bank layer 184. The emitting layer 186 may include an hole auxiliary layer, an emitting material layer (EML) and an electron auxiliary layer sequentially or reversely laminated. For example, the emitting layer 186 may include a hole injection layer (HIL), a hole transporting layer (HTL), the EML, an electron transporting layer (ETL) and an electron injection layer (EIL).

The white light may be provided from the emitting layer 186. For example, the emitting layer 186 may have a double-stack structure of a first stack including a blue EML and a second stack including a yellow-green EML. Alternatively, the emitting layer 186 may have a triple-stack structure of first and second stacks, each of which includes a blue EML, and a third stack, which includes a red EML and a green EML and is positioned between the first and second stacks.

The white light from the light emitting diode De passes through the red, green and blue color filters in the first to third subpixels SP1 to SP3 so that a full-color image is provided from the display device 110. In addition, the white light from the light emitting diode De is provided at the fourth subpixel SP4, where a color filter is not presented.

An upper electrode 188 is disposed on the emitting layer 186. The upper electrode 188 may be disposed over the entire display area DA. For example, the upper electrode 188 may extend into a portion of each of the first and second gate driving circuits 130 and 135. The upper electrode 188 may be formed of an opaque conductive material having a relatively high reflectance.

For example, the opaque conductive material may include a material having a relatively low work function such as aluminum (Al), silver (Ag), copper (Cu), lead (Pb), molybdenum (Mo), titanium (Ti) or an alloy thereof.

One of the lower and upper electrodes 182 and 188 is an anode, and the other one of the lower and upper electrodes 182 and 188 is a cathode.

The lower electrode 182, the emitting layer 186 and the upper electrode 188 constitute the light emitting diode De.

In FIG. 5, the lower electrode 182 includes a transparent material, and the upper electrode 188 includes an opaque material having a relatively high reflectance. Namely, the display device 110 has a bottom-emission type.

Alternatively, the display device 110 may have a top-emission type. Namely, the lower electrode 182 may include an opaque material having a relatively high reflectance, and the upper electrode 188 may include a transparent material. In this case, the color filter layer 178 may be disposed on or over the upper electrode 188.

A first encapsulating layer 190 and a second encapsulating layer 192 are sequentially disposed on the upper electrode 188 over the entire substrate 150. The first encapsulating layer 190 and the second encapsulating layer 192 may prevent a moisture or an oxygen of an exterior from permeating the light emitting diode De.

For example, the first encapsulating layer 190 may include a non-photosensitive organic insulating material such as acrylic resin, epoxy resin, phenolic resin, polyamide resin, polyimide resin, polyethylene and silicon oxycarbon (SiOC) or a photosensitive organic insulating material such as photoacryl, and the second encapsulating layer 192 may be a glass substrate, a plastic substrate or a metal plate.

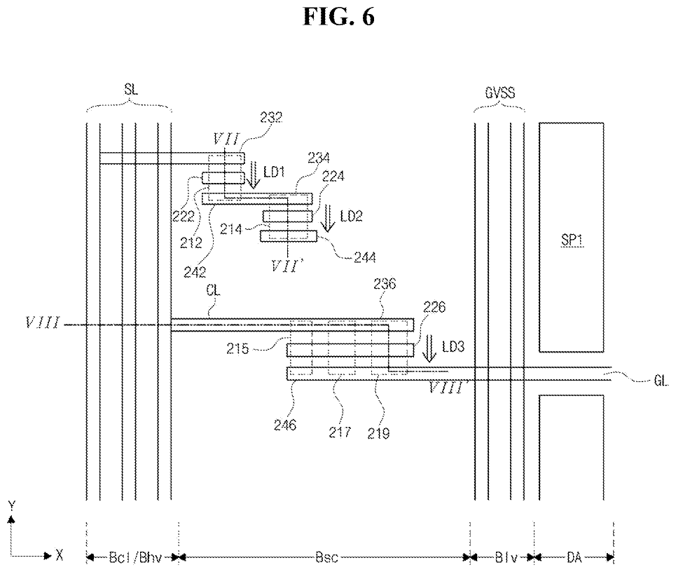

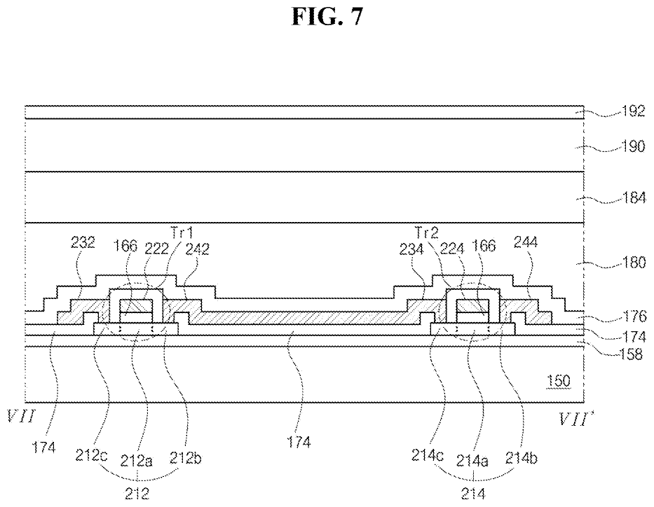

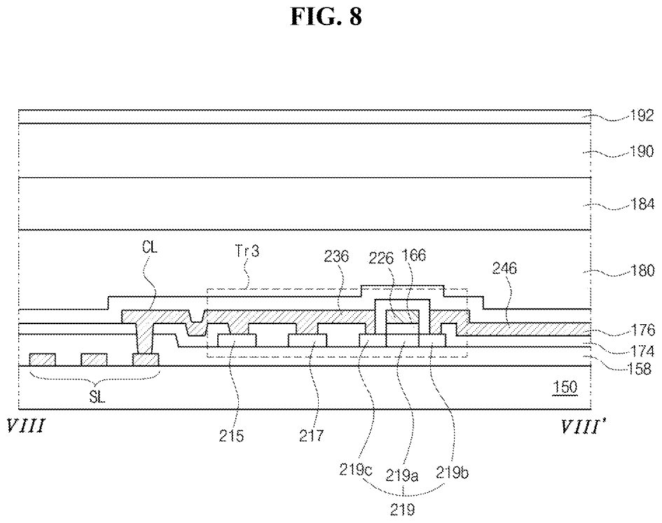

FIG. 6 is a schematic plan view showing a part of a display area and a gate driving circuit of a display device according to an embodiment of the present disclosure. FIG. 7 is a cross-sectional view taken along a line VII-VII′ in FIG. 6, and FIG. 8 is a cross-sectional view taken along a line VIII-VIII′ in FIG. 6.

Referring to FIGS. 6 to 8, the stage circuit block Bsc is disposed at an outer side of the display area DA. In addition, the low level voltage block Blv is disposed between the display area DA and the stage circuit block Bsc, and the clock signal block Bcl and the high level voltage block Bhv are disposed at an outer side of the stage circuit block Bsc.

A plurality of clock lines are disposed in the clock signal block Bcl, and a plurality of high level voltage lines are disposed in the high level voltage block Bhv. The plurality of clock lines and plurality of high level voltage lines may be referred to as a first signal line SL. Namely, the first signal line SL extending along a first direction Y is disposed in the clock signal block Bcl and the high level voltage block Bhv.

A plurality of low level voltage lines are disposed in the low level voltage block Blv. The plurality of low level voltage lines may be referred to as a second signal lines GVSS. Namely, the second signal line GVSS extending along the first direction Y is disposed in the low level voltage block Blv.

A plurality of transistors Tr1, Tr2 and Tr3 are disposed in the stage circuit block Bsc. In FIG. 6, three transistors Tr1, Tr2 and Tr3 are shown for the shake of explanation.

In at least one of the plurality of transistors Tr1, Tr2 and Tr3, a drain electrode may be connected to the first signal line SL. In addition, at least two of the plurality of transistors Tr1, Tr2 and Tr3 may be connected to each other. Moreover, in at least one of the plurality of transistors Tr1, Tr2 and Tr3, a source electrode may be connected to a gate line GL, which extends along a second direction X. The second direction X may cross the first direction Y. The second direction X may be perpendicular to the first direction Y. Namely, the gate driving circuit is disposed at one side of the display area DA in the second direction X, and the source electrode of at least one of the plurality of transistors Tr1, Tr2 and Tr3 in the gate driving circuit extends along the second direction. As a result, a gate signal can be provided into the subpixel.

The first transistor Tr1 includes a first channel, and the second transistor Tr2 includes a second channel. A length direction (e.g., a longitudinal direction) LD1 of the first channel is parallel to a length direction LD2 of the second channel.

The first transistor Tr1 includes a first active layer 212, a first gate electrode 222, a first drain electrode 232 and a first source electrode 242. The first active layer 212 includes a first channel region 212a and first source and drain regions 212b and 212c at both sides of the first channel region 212a. The first channel region 212a overlapping the first gate electrode 222 is defined as the first channel of the first transistor Tr1. A direction connecting the first drain region 212c and the first source region 212b and passing through the first channel region 212a is defined as the length direction LD1 of the first channel.

The second transistor Tr2 includes a second active layer 214, a second gate electrode 224, a second drain electrode 234 and a second source electrode 244. The second active layer 214 includes a second channel region 214a and second source and drain regions 214b and 214c at both sides of the second channel region 214a. The second channel region 214a overlapping the second gate electrode 224 is defined as the second channel of the second transistor Tr2. A direction connecting the second drain region 214c and the second source region 214b and passing through the second channel region 214a is defined as the length direction LD2 of the second channel.

Each of the first length direction LD1 of the first channel and the second length direction LD2 of the second channel is parallel to the first direction Y, which is an extension direction of the first signal line SL, and perpendicular to the second direction X, which is an extension direction of the gate line GL.

In the first transistor Tr1, the first drain electrode 232 may be connected to the first signal line SL through the connection line CL, and the length direction LD1 of the first channel may be perpendicular to the extension direction of the first drain electrode 232 and the extension direction of the connection line CL. In addition, the length direction LD1 of the first channel may be perpendicular to the extension direction of the first gate electrode 222 and the extension direction of the first source electrode 242.

In the second transistor Tr2, the second drain electrode 234 may be connected to the first source electrode 242 of the first transistor Tr1, and the length direction LD2 of the second channel may be perpendicular to the extension direction of the second drain electrode 234. In addition, the length direction LD2 of the second channel may be perpendicular to the extension direction of the second gate electrode 224 and the extension direction of the second source electrode 244.

The third transistor Tr3 includes third active layers 215, 217 and 219, a third gate electrode 226, a third drain electrode 236 and a third source electrode 246. Each of the third active layers 215, 217 and 219 includes a third channel region and third source and drain regions at both sides of the third channel region. The third channel region overlapping the third gate electrode 226 is defined as the first channel of the third transistor Tr3. A direction connecting the third drain region and the third source region and passing through the third channel region is defined as the length direction LD3 of the third channel.

In FIG. 6, the third transistor Tr3 includes three active layers 215, 217 and 219 being separated from each other. Alternatively, the active layers 215, 217 and 219 may be connected to each other to have a single island shape.

The length direction LD3 of the third channel may be parallel to each of the length direction LD1 of the first channel and the length direction LD2 of the second channel and may be perpendicular to the second direction X, which is the extension direction of the gate line GL.

In the third transistor Tr3, the third drain electrode 236 may be connected to the first signal line SL through the connection line CL, and the length direction LD3 of the third channel may be perpendicular to the extension direction of the third drain electrode 236 and the extension direction of the connection line CL. In addition, the length direction LD3 of the third channel may be perpendicular to the extension direction of the third gate electrode 226 and the extension direction of the third source electrode 246.

In an aspect of the present disclosure, in the plurality of transistors Tr1, Tr2 and Tr3 in the gate driving circuit, the length directions LD1, LD2 and LD3 of the channels are parallel to each other. In an aspect of the present disclosure, in all of the plurality of transistors in the gate driving circuit, the length directions LD1, LD2 and LD3 of the channels are parallel to each other. As a result, the property of the plurality of transistors Tr1, Tr2 and Tr3 in the gate driving circuit can be uniformed. In addition, the length direction LD1, LD2 and LD3 of the channel of the plurality of transistors Tr1, Tr2 and Tr3 in the gate driving circuit may be same as a length direction of the channel of the driving transistor Td.

Moreover, the extension direction of each of the gate electrode, the source electrode and the drain electrode of the plurality of transistors Tr1, Tr2 and Tr3 in the gate driving circuit may be parallel to the extension direction of the lines, which is connected to the plurality of transistors Tr1, Tr2 and Tr3. As a result, the length of the line in the gate driving circuit can be reduced or minimized and the resistance of the line can be decreased so that the low power operation can be realized.

Furthermore, since the area occupied by the line in the gate driving circuit is decreased, a narrow bezel display device can be realized.

Referring to FIGS. 6 to 8 with FIG. 5, the first signal line SL and the second signal line GVSS are formed on the substrate 150. Each of the first signal line SL and the second signal line GVSS are disposed at the same layer and formed of the same material as the light shielding layer 152.

The buffer layer 158 is formed on the first signal line SL and the second signal line GVSS.

The first active layer 212, the second active layer 214 and the third active layer 215, 217 and 219 are formed on the buffer layer 158. Each of the first active layer 212, the second active layer 214 and the third active layer 215, 217 and 219 are disposed at the same layer and formed of the same material as the active layer 160. The first active layer 212 includes a first channel region 212a and first source and drain regions 212b and 212c at both sides of the first channel region 212a, and the second active layer 214 includes a second channel region 214a and second source and drain regions 214b and 214c at both sides of the second channel region 214a. The third active layer 219 includes a third channel region 219a and third source and drain regions 219b and 219c at both sides of the third channel region 219a.

Each of the first to third channel regions 212a, 214a and 219a is formed of an intrinsic semiconductor material, and each of the first to third source regions 212b, 214b and 219b and the first to third drain regions 212c, 214c and 219c is formed of an impurity-doped semiconductor material.

The gate insulating layer 166, which is pattered, is formed on the first active layer 212, the second active layer 214 and the third active layer 215, 217 and 219.

The first to third gate electrodes 222, 224 and 226, which respectively correspond to the first channel region 212a of the first active layer 212, the second channel region 214a of the second active layer 214 and the third channel region 219a of the third active layer 219, are formed on the gate insulating layer 166. Each of the first to third gate electrodes 222, 224 and 226 is disposed at the same layer and formed of the same material as the gate electrode 168.

The impurity of the first to third source regions 212b, 214b and 219b and the first to third drain regions 212c, 214c and 219c may be doped respectively using the first to third gate electrodes 222, 224 and 226 as a blocking mask. As a result, the first gate electrode 222 and the first channel region 212a may have the same area and completely overlap with each other, the second gate electrode 224 and the second channel region 214a may have the same area and completely overlap with each other, and the third gate electrode 226 and the third channel region 219a may have the same area and completely overlap with each other.

The first interlayer insulating layer 174, which includes contact holes respectively exposing the first to third source regions 212b, 214b and 219b and the first to third drain regions 212c, 214c and 219c, is formed on the first to third gate electrodes 222, 224 and 226. In addition, a contact hole exposing a portion of the first signal line SL may be formed through the first interlayer insulating layer 174 and the buffer layer 158.

The first drain electrode 232 and the first source electrode 242, which are spaced apart from each other, the second drain electrode 234 and the second source electrode 244, which are spaced apart from each other, and the third drain electrode 236 and the third source electrode 246, which are spaced apart from each other, are disposed on the first interlayer insulating layer 174.

The first drain electrode 232 contacts the first drain region 212c of the first active layer 212, and the first source electrode 242 contacts the first source region 212b of the first active layer 212. The second drain electrode 234 contacts the second drain region 214c of the second active layer 214, and the second source electrode 244 contacts the second source region 214b of the second active layer 214. The third drain electrode 236 contacts the third drain region 219c of the third active layer 219, and the third source electrode 246 contacts the third source region 219b of the third active layer 219.

In addition, the connection line CL, which is connected to the first signal line SL through the contact hole, is formed on the first interlayer insulating layer 174. The connection line CL is connected to the third drain electrode 236.

Each of the first to third drain electrodes 232, 234 and 236, the first to third source electrodes 242, 244, 246 and the connection line CL are disposed at the same layer and formed of the same material as the source electrode 170.

The first active layer 212, the first gate electrode 222, the first source electrode 242 and the first drain electrode 232 constitute the first transistor T1. The second active layer 214, the second gate electrode 224, the second source electrode 244 and the second drain electrode 234 constitute the second transistor T2. The third active layers 215, 217 and 219, the third gate electrode 226, the third source electrode 246 and the third drain electrode 236 constitute the third transistor T3.

The second interlayer insulating layer 176 is formed on the first to third drain electrodes 232, 234 and 236, the first to third source electrodes 242, 244, 246 and the connection line CL, and the overcoat layer 180 is formed on the second interlayer insulating layer 176.

The first and second encapsulation layers 190 and 192 are sequentially formed on the overcoat layer 180.

In FIGS. 7 and 8, the first and second encapsulation layers 190 and 192 are sequentially stacked on the bank layer 184 in the gate driving circuit. Namely, the emitting layer 186 and the upper electrode 188 of the light emitting diode De are not formed in the gate driving circuit.

Alternatively, each of the emitting layer 186 and the upper electrode 188 may extend into a portion of the gate driving circuit. For example, the emitting layer 186 may extend into a portion of the stage circuit block Bsc, and the upper electrode 188 may be formed to cover a side of the emitting layer 186.

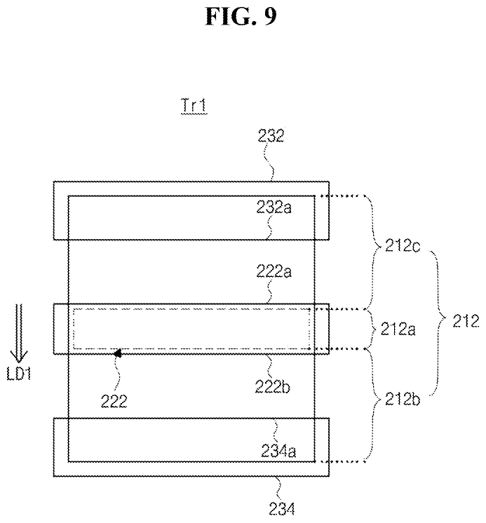

FIG. 9 is a schematic plan view showing a transistor in a gate driving circuit of a display device according to an embodiment of the present disclosure.

Referring to FIG. 9 with FIGS. 5 to 8, the first transistor Tr1 includes the first active layer 212, which includes the first channel region 212a, the first source region 212b and the first drain region 212c, the first gate electrode 222 overlapping the first channel region 212a, the first drain electrode 232 contacting the first drain region 212c and the first source electrode 242 contacting the first source region 212b. The length direction of the first channel in the first transistor Tr1 is defined as a direction connecting a boundary line between the first channel region 212a and the first drain region 212c and a boundary line between the first channel region 212a and the first source region 212b.

In this case, the length direction LD1 of the first channel in the first transistor Tr1 is parallel to at least one of the length direction LD2 of the channel of the second transistor Tr2 and the length direction LD3 of the channel of the third transistor Tr3.

As described above, since the impurity is doped into the active layer using the gate electrode as a blocking mask, the length direction LD1 of the first channel is perpendicular to the extension direction of the first gate electrode 222. Namely, each of a first side surface 222a, which faces the first drain electrode 232, of the first gate electrode 222 and a second side surface 222b, which faces the first source electrode 242, of the first gate electrode 222 is perpendicular to the length direction LD1 of the first channel.

For example, the length direction LD1 of the first channel in the first transistor Tr1 may be parallel to the first direction Y, which is the extension direction of the first signal line SL, and may be perpendicular to the second direction X, which is the extension direction of the connection line CL.

Each of the extension direction of the first drain electrode 232 and the extension direction of the first source electrode 242 may be perpendicular to the length direction LD1 of the first channel and may be parallel to the extension direction of the first gate electrode 222. Each of the extension direction of the first drain electrode 232 and the extension direction of the first source electrode 242 may be parallel to the second direction X, which is the extension direction of the connection line CL. In this case, the length of the line in the gate driving circuit can be reduced or minimized.

For example, the first drain electrode 232 may have a side surface 232a facing the first side surface 222a of the first gate electrode 222, and the first source electrode 242 may have a side surface 242a facing the second side surface 222b of the first gate electrode 222. The side surface 232a of the first drain electrode 232 and the side surface 242a of the first source electrode 242 may be parallel to the first side surface 222a and the second side surface 222b of the first gate electrode 222, respectively.

Alternatively, each of the extension direction of the first drain electrode 232 and the extension direction of the first source electrode 242 may be inclined to the length direction LD1 of the first channel and the extension direction of the first gate electrode 222. Since the shape of the arrangement of the first drain electrode 232 and the first source electrode 242 do not affect the length direction of the channel, the extension direction of the first drain electrode 232 and the extension direction of the first source electrode 242 may be different from the extension direction of the first gate electrode 222. However, as described above, when each of the extending directions of the first drain electrode 232 and the extending direction of the first source electrode 242 is parallel to the extending direction of the first gate electrode 222, i.e., the second direction X, the length of the line in the gate driving circuit is reduced or minimized so that there is an advantage of enabling low-power operation.

It will be apparent to those skilled in the art that various modifications and variation can be made in the present disclosure without departing from the scope of the disclosure. Thus, it is intended that the present disclosure cover the modifications and variations of this disclosure provided they come within the scope of the appended claims.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a display area and a non-display area adjacent to the display area, the display area including a subpixel;
a gate driving circuit disposed in the non-display area, the gate driving circuit generating a gate signal and including a plurality of blocks;
a first transistor disposed in the gate driving circuit and including a first channel; and
a second transistor disposed in the gate driving circuit and including a second channel,
wherein a first length direction of the first channel is in the same direction as a second length direction of the second channel.

2. The display device according to claim 1, further comprising a light emitting diode in the subpixel and over the substrate.

3. The display device according to claim 2, further comprising a signal line disposed in the gate driving circuit and extending along a first direction,
wherein the first length direction is parallel to the first direction.

4. The display device according to claim 3, further comprising a connection line electrically connecting the signal line and the first transistor,
wherein the connection line extends along a second direction crossing the first direction.

5. The display device according to claim 4, wherein the first and second directions are perpendicular to each other.

6. The display device according to claim 4, wherein the gate driving circuit is disposed at one side of the display area in the second direction.

7. The display device according to claim 4, wherein the first transistor includes a first active layer, a first gate electrode, a first source electrode, and a first drain electrode,
wherein the second transistor includes a second active layer, a second gate electrode, a second source electrode, and a second drain electrode, and
wherein each of the first and second source electrodes and the first and second drain electrodes is disposed at the same layer as the connection line.

8. The display device according to claim 7, wherein each of the first and second source electrodes and the first and second drain electrodes is parallel to the connection line.

9. The display device according to claim 7, wherein each of the first and second gate electrodes is parallel to the connection line.

10. The display device according to claim 3, further comprising:
a driving transistor disposed between the substrate and the light emitting diode in the subpixel;
a light shielding layer disposed between the substrate and the driving transistor; and
a buffer layer disposed between the driving transistor and the light shielding layer,
wherein the signal line is disposed at the same layer as the light shielding layer.

11. The display device according to claim 10, wherein the driving transistor includes a third channel, and a third length direction of the third channel is parallel to each of the first length direction and the second length direction.

12. The display device according to claim 1, wherein the first transistor includes a first active layer, a first gate electrode, a first source electrode and a first drain electrode, and the second transistor includes a second active layer, a second gate electrode, a second source electrode and a second drain electrode, and
wherein the first gate electrode includes a first side surface facing the first drain electrode and a second side surface facing the first source electrode, and each of the first and second side surfaces is perpendicular to the first length direction.

13. The display device according to claim 12, wherein the first drain electrode includes a side surface facing the first side surface, and the first source electrode includes a side surface facing the second side surface, and
wherein each of the side surface of the first drain electrode and the side surface of the first source electrode is perpendicular to the first length direction.

14. The display device according to claim 12, wherein the first drain electrode includes a side surface facing the first side surface, and the first source electrode includes a side surface facing the second side surface, and
wherein each of the side surface of the first drain electrode and the side surface of the first source electrode is inclined to the first length direction.

15. The display device according to claim 12, wherein the second gate electrode includes a third side surface facing the second drain electrode and a fourth side surface facing the second source electrode, and each of the third and fourth side surfaces is perpendicular to the second length direction.

16. The display device according to claim 1, wherein the second transistor includes a second active layer, a second gate electrode, a second source electrode and a second drain electrode, and
wherein the second gate electrode includes a third side surface facing the second drain electrode and a fourth side surface facing the second source electrode, and each of the third and fourth side surfaces is perpendicular to the second length direction.

17. The display device according to claim 16, wherein the second drain electrode includes a side surface facing the third side surface, and the second source electrode includes a side surface facing the fourth side surface, and
wherein each of the side surface of the second drain electrode and the side surface of the second source electrode is perpendicular to the second length direction.

18. The display device according to claim 16, wherein the second drain electrode includes a side surface facing the third side surface, and the second source electrode includes a side surface facing the fourth side surface, and
wherein each of the side surface of the second drain electrode and the side surface of the second source electrode is inclined to the second length direction.

19. A display device, comprising:
a substrate including a display area and a non-display area adjacent to the display area, the display area including a subpixel;
a gate driving circuit disposed in the non-display area, the gate driving circuit generating a gate signal and including a plurality of blocks;
a first transistor disposed in the gate driving circuit and including a first active layer, a first gate electrode, a first source electrode, and a first drain electrode; and
a second transistor disposed in the gate driving circuit and including a second active layer, a second gate electrode, a second source electrode, and a second drain electrode,
wherein each of the first drain electrode, the second drain electrode, the first source electrode, and second source electrode extends along a first direction.

20. The display device according to claim 19, further comprising a light emitting diode in the subpixel and over the substrate.

21. The display device according to claim 19, further comprising:
a signal line disposed in the gate driving circuit and extending along a second direction; and
a connection line electrically connecting the signal line and the first drain electrode,
wherein an extension direction of the connection line is parallel to the first direction.

22. The display device according to claim 21, wherein the first direction is perpendicular to the second direction.
